(19) United States
(12) Patent Application Publication
(10) Pub. No.: US 2022/0154985 A1
(43) Pub. Date: May 19, 2022

(54) HEAT DISSIPATION DEVICE

(71) Applicants: Inventec (Pudong) Technology Corporation, Shanghai (CN); INVENTEC CORPORATION, Taipei City (TW)

(72) Inventors: Kai-Yang TUNG, TAIPEI CITY (TW); Hung-Ju CHEN, TAIPEI CITY (TW)

(21) Appl. No.: 17/343,758

(22) Filed: Jun. 10, 2021

(30) Foreign Application Priority Data
Nov. 19, 2020 (CN) 202011302485.1

(51) Int. Cl. F25B 41/40; F25B 39/02; F25B 25/00

(52) U.S. Cl. CPC F25B 41/40; F25B 2339/047; F25B 25/005; F25B 39/02

(57) ABSTRACT

A heat dissipation device includes a first pipeline and a second pipeline. The first pipeline is configured to circulate a first fluid. The second pipeline is configured to circulate a second fluid. The second pipeline has a sleeve portion. The sleeve portion is sleeved with a part of the first pipeline to form a circulation tunnel therebetween. One of the sleeve portions and the part of the first pipeline has a first surface and a second surface. The first surface contacts the first fluid. The second surface contacts the second fluid. The second surface has a plurality of protruding strips.

### CROSS-REFERENCE TO RELATED APPLICATION

This application claims priority to China Application Serial Number 202011302485.1 filed Nov. 19, 2020, which is herein incorporated by reference in its entirety.

### BACKGROUND

### Field of Disclosure

The present disclosure relates to a heat dissipation device.

### Description of Related Art

In an open thermosiphon heat dissipation device that includes a double layer pipeline, refrigerant and cooling water flow inside the double layer pipeline, respectively. This type of heat dissipation device cools down the refrigerant through the thermal exchange of the fluids inside the double layer pipeline and thus forming a cycling heat dissipation loop. In order to reduce the energy consumption of the cooling water pump in operation of the heat dissipation device, thus the heat dissipation device in prior art designs the double-layer pipeline has a smooth pipe wall.

However, although the smooth pipe wall can reduce the energy consumption of the cooling water pump, it also causes the cooling water to flow in a laminar flow. When the fluid flows in a laminar flow, it will affect the heat distribution inside the fluid, which in turn affects the thermal exchange between the two fluids. The thermal exchange between the two fluids will affect the heat dissipation efficiency of the heat dissipation device.

Therefore, how to provide a heat dissipation device to solve the above problems becomes an important issue to be solved by those in the industry.

### SUMMARY

The disclosure provides a heat dissipation device, comprising: a first pipeline and a second pipeline. The first pipeline is configured to circulate a first fluid. The second pipeline is configured to circulate a second fluid and includes a sleeve portion. The sleeve portion is sleeved with a part of the first pipeline to form a circulation tunnel between the sleeve portion and the part of the first pipeline. One of the sleeve portions and the part of the first pipeline includes: a first surface and a second surface. The first surface is configured to contact the first fluid. The second surface is configured to contact the second fluid and has a plurality of protruding strips.

In another embodiment, the first surface has a plurality of sharp points.

In yet another embodiment, the first surface has at least one groove. The at least one groove is located on a side of the first surface. The at least one groove substantially extends along the one of the sleeve portion and the part of the first pipeline and is circumferentially arranged.

In yet another embodiment, the protruding strips are spiral and are sequentially arranged.

In yet another embodiment, the protruding strips substantially extend along an extending direction of the one of the sleeve portion and the part of the first pipeline.

In yet another embodiment, heat dissipation device further comprises an input portion and an output portion that are connected to the sleeve portion respectively.

In yet another embodiment, the sleeve portion is sleeved outside the part of the first pipeline. The circulation tunnel is configured to circulate the second fluid. The first surface is located on an inner side of the first pipeline. The second surface is located on an outer side of the first pipeline.

In yet another embodiment, the sleeve portion is sleeved inside the part of the first pipeline. The circulation tunnel is configured to circulate the first fluid. The first surface is located on an outer side of the second pipeline. The second surface is located on an inner side of the second pipeline.

In yet another embodiment, the heat dissipation device includes an evaporator. The evaporator is connected to two sides of the first pipeline.

In yet another embodiment, wherein the first fluid is a refrigerant and the second fluid is water.

According to the above description, in the present disclosure, the second surface that contacts the second fluid has protruding stripes. The protruding stripes can make the second fluid flow in turbulent flow. The turbulent flow can uniformly distribute the heat of the second fluid and increase the thermal exchange efficiency between the second fluid and the first fluid, thus increasing the heat dissipation efficiency of the heat dissipation device. Moreover, the first surface that contacts the first fluid has sharp points to increase the condensation efficiency for the first fluid on the first surface. The above structure can further combine with grooves on the first surface, thus making the condensed first fluid flow more smoothly, and improve the flowing efficiency of the first fluid. The flowing efficiency of the first fluid can further increase the heat dissipation efficiency of the heat dissipation device.

In one of the embodiments of the present disclosure, the servers can be used in AI (Artificial Intelligence) calculation, edge computing, also can serve as 5G servers, cloud servers or internet of vehicles.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective view of a heat dissipation device according to one embodiment of this disclosure;

FIG. 2A is a partial cross-sectional view of a heat dissipation device according to one embodiment of this disclosure;

FIG. 2B is a partial perspective view of the heat dissipation device in FIG. 2A;

FIG. 3 is a cross-sectional view of a part of a heat dissipation device according to another embodiment of this disclosure;

FIG. 4 is a three dimensional cross-sectional view of a sleeve portion of a cut through of a heat dissipation device according to another embodiment of this disclosure;

FIG. 5 is a three dimensional cross-sectional view of a sleeve portion of a cut through of a heat dissipation device according to another embodiment of this disclosure;

FIG. 6 is a diagram of the mechanical energy and the input flow velocity of different types of second surface of a heat dissipation device;

FIG. 7 is a diagram of the heat dissipation ability and the mechanical energy of different types of second surface of a heat dissipation device;

FIG. 8A is a cross-sectional view of a part of a first pipeline of a heat dissipation device according to one embodiment of this disclosure; and

FIG. 8B is a cross-sectional view of a part of a first pipeline of a heat dissipation device according to another embodiment of this disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

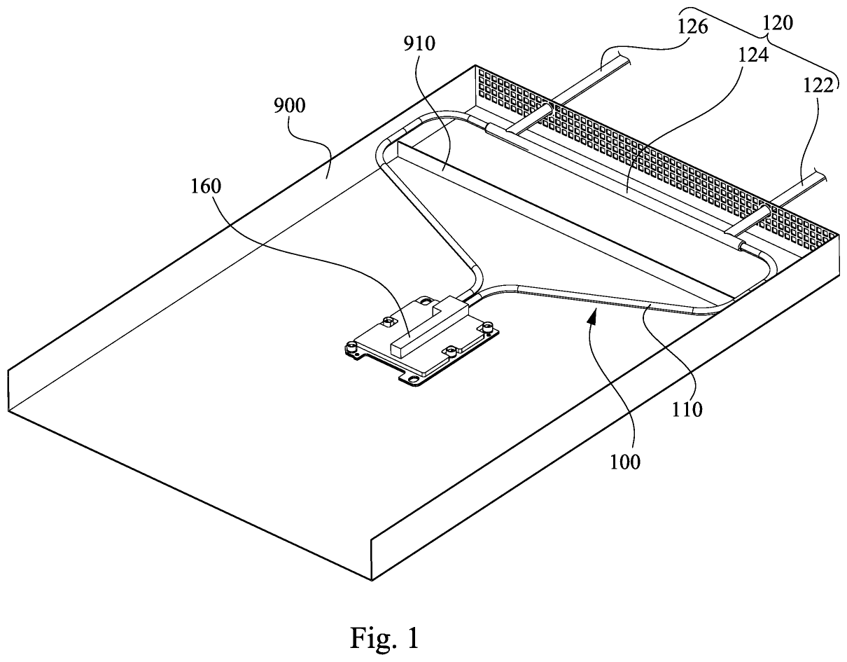

Reference is made to FIG. 1. FIG. 1 is a perspective view of a heat dissipation device according to one embodiment of this disclosure. According to FIG. 1, the heat dissipation device 100 includes a first pipeline 110 and a second pipeline 120. In some embodiments, the materials of manufacturing the first pipeline 110 and the second pipeline 120 includes copper or aluminum, but the present disclosure is not limited thereto. In some embodiments, the shape of the cross section of the first pipeline 110 and the second pipeline 120 is in circle or square, but the present disclosure is not limited thereto. In some embodiments, an evaporator 160 is configured to directly contact the heat source (not shown) of the housing 900, and conducts heat to the first pipeline 110.

As shown in FIG. 1, the heat dissipation device 100 has been installed inside the housing 900 (e.g. a housing of a server). An input portion 126 and the output portion 122 of the heat dissipation device 100 pass through a side of the housing 900 and extend outside the housing 900. The sleeve portion 124 of the heat dissipation device 100 and the evaporator 160 are isolated in two different areas by an isolator 910 of the housing 900.

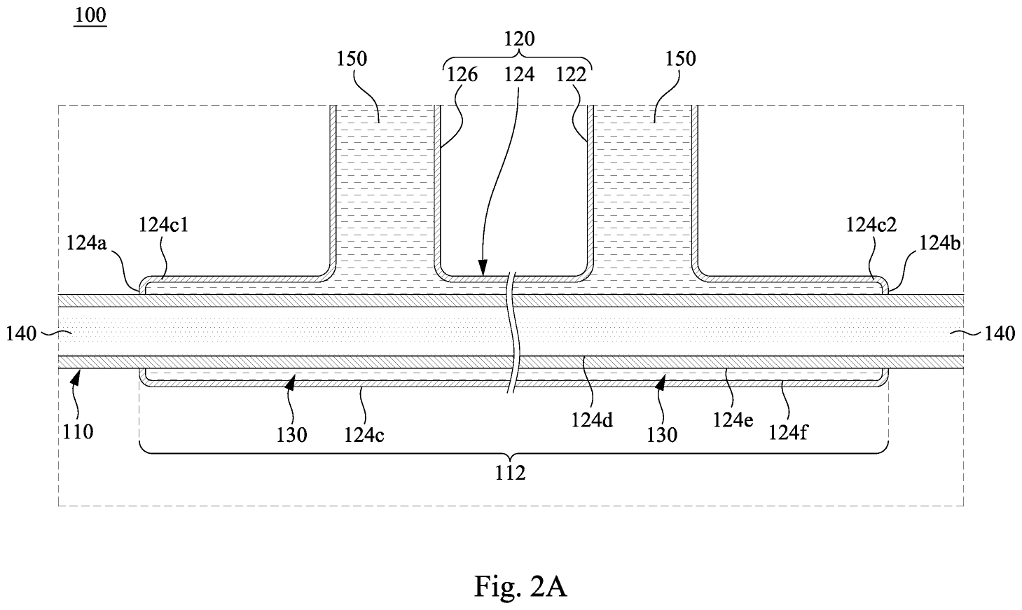

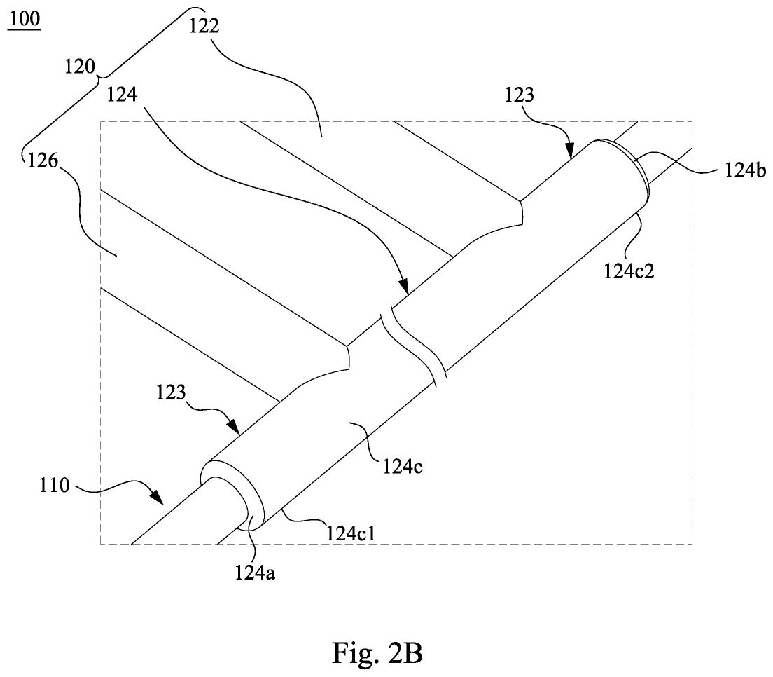

Reference is made to FIG. 2A. FIG. 2A is a partial cross-sectional view of a part of a heat dissipation device according to one embodiment of this disclosure. As shown in FIG. 2A, the first pipeline 110 circulates a first fluid 140. The second pipeline 120 circulates a second fluid 150. The first surface 124d is located on the inner side of the first pipeline 110. The second surface 124e is located on the outer side of the first pipeline 110. For example, the first fluid 140 is refrigerant and contacts the first surface 124d, the second fluid 150 is cooling water and contacts the second surface 124e, but the present disclosure is not limited thereto. As shown in FIG. 1 and FIG. 2A, the second pipeline 120 has a sleeve portion 124, an input portion 126 and an output portion 122. The sleeve portion 124 of the second pipeline 120 is sleeved with a part 112 of the first pipeline 110. The circulation tunnel 130 is formed between the sleeve portion 124 and the part 112 of the first pipeline 110. The input portion 126 and the output portion 122 of the second pipeline 120 are connected to the sleeve portion 124 respectively.

In a specific embodiment of the present disclosure, as shown in FIG. 2A, the sleeve portion 124 of the second pipeline 120 is sleeved outside the part 112 of the first pipeline 110. The first fluid 140 circulates inside the first pipeline 110 and the second fluid 150 circulates inside the circulation tunnel 130. According to one example of the above embodiment, wherein the first fluid 140 is refrigerant, the second fluid 150 is cooling water. The refrigerant and the cooling water can achieve thermal equilibrium through the thermal conduction of the part 112 of the first pipeline 110, and thus cooling down the refrigerant. The principle of cooling down the refrigerant is when the first fluid 140 that circulating in the first pipeline 110 passes through the sleeve portion 124 of the second pipeline 120, the second fluid 150 and the first fluid 140 achieve thermal equilibrium through the thermal conduction of the part 112 of the first pipeline 110. For example, in a specific embodiment, the first fluid 140 is refrigerant, the refrigerant will phase change to gaseous state under high temperature. When the gaseous refrigerant flows through the sleeve portion 124, the gaseous refrigerant is cooled down through the thermal exchange with the second fluid 150 (in some embodiments, the second fluid 150 is cooling water). The cool downed gaseous refrigerant condenses on the inner side of the first pipeline 110 and phase changes to liquid refrigerant.

Reference is made to FIG. 2B. FIG. 2B is a perspective view of a part of the heat dissipation device in FIG. 2A. As shown in FIG. 2B, the sleeve portion 124 of the second pipeline 120 includes a cover part 124c, a first sealing part 124a and a second sealing part 124b. The cover part 124c covers the part 112 of the first pipeline 110, and has a first end 124c1 and a second end 124c2. The first sealing part 124a is hermetically connected to the first end 124c1 and the first pipeline 110. The second sealing part 124b is hermetically connected to the second end 124c2 and the first pipeline 110. In other words, the first sealing part 124a and the second sealing part 124b that are hermetically connected forming two structures which can be seen as blind tube structures 123. Both blind tube structures 123 extend from the first end 124c1 and the second end 124c2 of the cover part 124c. More specifically, the blind tube structure 123 is formed by the first sealing part 124a and the cover part 124c that are located between the first end 124c1 and the input portion 126. The second sealing part 124b and the cover part 124c which are located between the second end 124c2 and the output portion 126 form another blind tube structure 123. The connection of the input portion 126 and the output portion 122 of the second pipeline 120 and the sleeve portion 124 are located between the first end 124c1 and the second end 124c2 of the cover part 124c.

As the embodiment shown in FIG. 2B, the above blind tube structure 123 is the extension of the cover part 124c of the second pipeline 120 which extends out along the part 112 of the first pipeline 110. On the two ends of the blind tube structure 123, the circulation tunnel 130 between the first pipeline 110 and the second pipeline 120 (please see FIG. 2A) is sealed to prevent the second fluid leaking out of the heat dissipation device 100. In other words, in some specific embodiments, one of the input portion 126 and output portion 122 will form a T shape structure with the cover part 124c. This kind of T shape structure will reduce the manufacturing difficulties of the heat dissipation device 100. For example, in the actual manufacturing steps of the heat dissipation device, if coincides the first sealing part 124a with the surface of the connection part of the input portion 126 and the cover part 124c, the non-uniform surface formed by thereof will increase the welding difficulties. Thus the above T shape structure is utilized to separate the welding surfaces, and reduces the manufacturing difficulties.

As shown in FIG. 2A, in a specific embodiment of the present disclosure, the first pipeline 110 and the first end 124c1 and the second end 124c2 of the cover part 124c are hermetically connected through the first sealing part 124a and the second sealing part 124b respectively to prevent the second fluid 150 leaking out of the heat dissipation device 100. That is, the connected surface between the first pipeline 110 and the cover part 124c is formed by the first sealing part 124a and the second sealing part 124b. Between the first sealing part 124a and the second sealing part 124b, the input portion 126 and the output portion 122 are connected to the cover part 124c of the second pipeline 120 respectively.

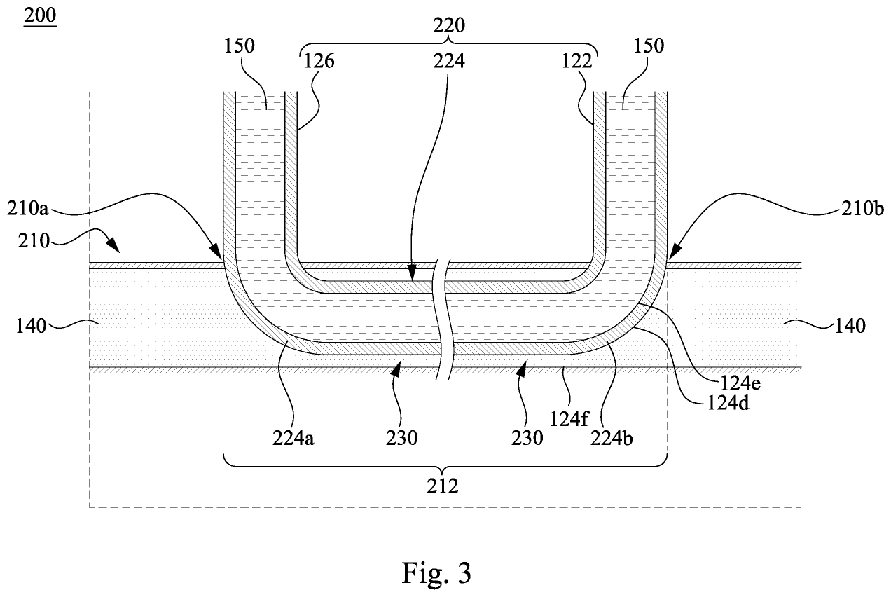

Reference is made to FIG. 3. FIG. 3 is a cross-sectional view of a part of a heat dissipation device, according to another embodiment of this disclosure. As shown in FIG. 3, the first pipeline 210 has two holes 210a, 210b and a part 212 is sleeved with the second pipeline 220. The second pipeline 220 has a sleeve portion 224, an input portion 126 and an output portion 122. The structure of the input portion 126 and the output portion 122 is similar or the same as the heat dissipation device 100, and not repeated herein. The sleeve portion 224 of the second pipeline 220 is sleeved inside the part 212 of the first pipeline 210. The circulation tunnel 230 is located between the first pipeline 210 and the sleeve portion 224 circulates the first fluid 140. The sleeve portion 224 has opposite two ends 224a, 224b. The input portion and the output portion 122 are connected to the two ends 224a, 224b of the sleeve portion 224 respectively. The two ends 224a, 224b of the sleeve portion 224 pass out from the two holes 210a, 210b of the first pipeline 210, and are connected with the input portion 126 and the output portion 122 hermetically to prevent the first fluid 140 leaking out from the connection surface. The first surface 124d is located on the outside of the second pipeline 220, and contacts the first fluid 140. The second surface is located on the inside of the second pipeline 220 and contacts the second fluid 150.

According to the above structure, the first fluid 140 circulates in the first pipeline 210 passes through the sleeve portion 224 of the second pipeline 220, the second fluid 150 and the first fluid 140 can achieve thermal equilibrium through the thermal conduction of the pipe wall of the sleeve portion 224.

Reference is made to FIG. 1, in some embodiments, the first pipeline 110 and the second pipeline 120 in FIG. 1 can be replaced by the first pipeline 210 and the second pipeline 220 in FIG. 3. The first fluid 140 and the second fluid 150 can achieve thermal equilibrium through the thermal conduction of the pipe wall of the sleeve portion 224 of the second pipeline 220. Reference is made to FIG. 1, in some embodiments, the outside of the sleeve portion 124, 224 can install exhaust devices (not shown, e.g. fans) to help cooling down the heat dissipation device 100.

The description below will focus on the structure feature and some embodiments of the first surface 124d and the second surface 124e respectively. In the following paragraph, the example of the heat dissipation device with the first surface 124d and the second surface 124e is located on the inner wall and the outer wall of the first pipeline 110 respectively will be taken as the example. In the example, the first pipeline 110 is sleeved inside by the second pipeline 120, and the circulation tunnel 130 between the first pipeline 110 and the second pipeline 120 (e.g. the structure shown in FIG. 2A), but the present disclosure is not limited thereto.

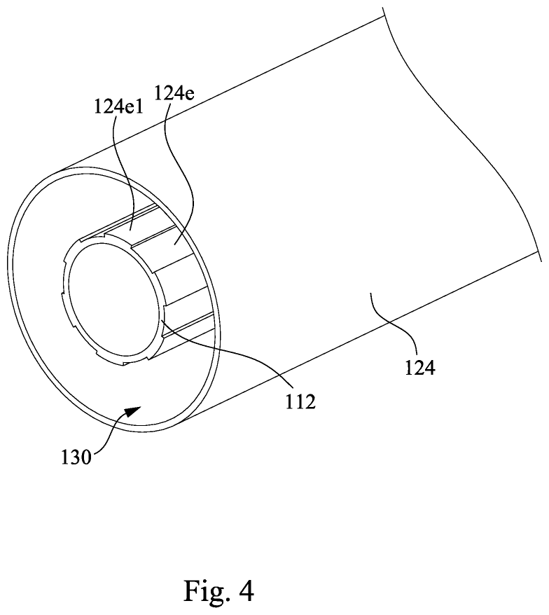

FIG. 4 is a 3D three dimensional cross-sectional view of a sleeve portion of a cut through of a heat dissipation device according to another embodiment of this disclosure. As shown in FIG. 4, the second surface 124e has protruding strips 124e1 structure. In some embodiments, the protruding strips 124e1 substantially extend along the extending direction of the part 112 of the first pipeline 110, and are circumferentially arranged on the part 112 of the first pipeline 110. In the illustration of FIG. 4, the number of the protruding strips 124e1 is six, but the present disclosure is not limited thereto. References are made to FIG. 2A and FIG. 4. The second fluid 150 (e.g. water) circulates in the circulation tunnel 130. The protruding strips 124e1 on the second surface 124e interfere with the circulation of the second fluid 150, which makes the second fluid 150 become a turbulent flow. The turbulent flow helps to uniform the heat distribution of the second fluid 150, and thus achieve better thermal conduction between the second fluid 150 and the first fluid 140.

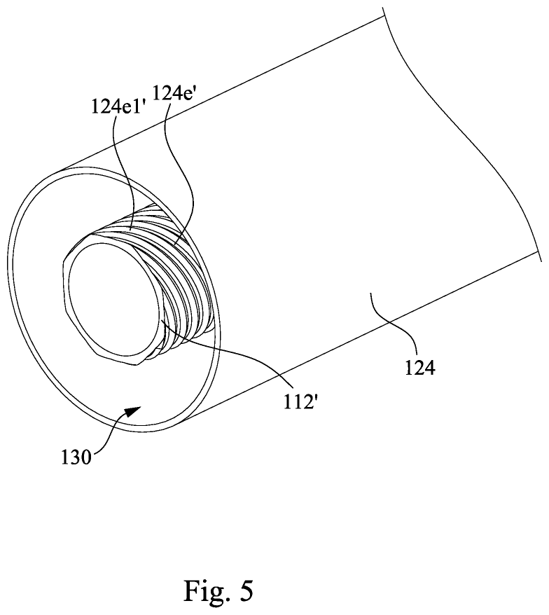

FIG. 5 is a 3D three dimensional cross sectional view of a sleeve portion of a cut through of a heat dissipation device according to another embodiment of this disclosure. As shown in FIG. 5, the second surface 124e′ has protruding strips 124e1′ structure. In some embodiments, protruding strips 124e1′ on the part 112′ of the first pipeline 110 is sequentially arranged in a spiral shape (like the shape of the screw). FIG. 4 and FIG. 5 are different embodiments of the protruding strips 124e1, the two embodiments both have the ability to interfere with the second fluid 150, but the present disclosure is not limited thereto.

In some embodiments, a heat dissipation device 200 has the structure that is shown FIG. 3. The second surface 124e has protruding strips 124e1, and is located on the inner side of the second pipeline 220 to contact the second fluid 150. Two of the embodiments of the protruding strips 124e1 are the same structure shown in FIG. 4 and FIG. 5, but the present disclosure is not limited thereto. The protruding strips 124e1 of the second surface 124e have the ability of making the second fluid 150 become a turbulent flow. The turbulent flow helps to uniform the heat distribution of the second fluid 150, and thus can achieve better thermal conduction between the second fluid 150 and the first fluid 140.

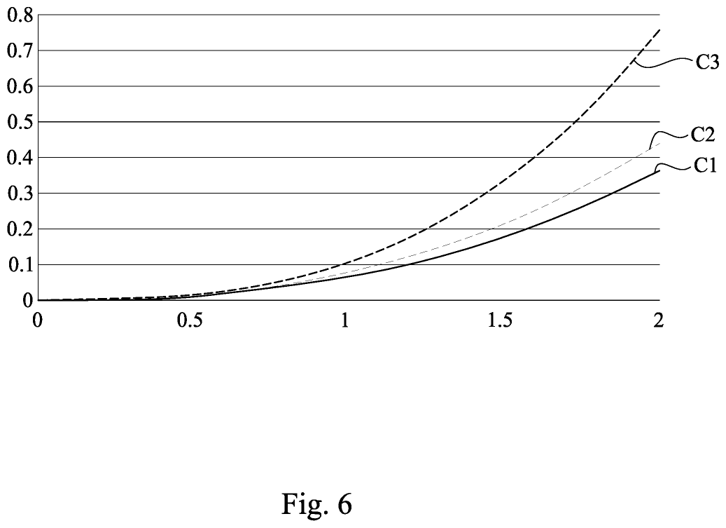

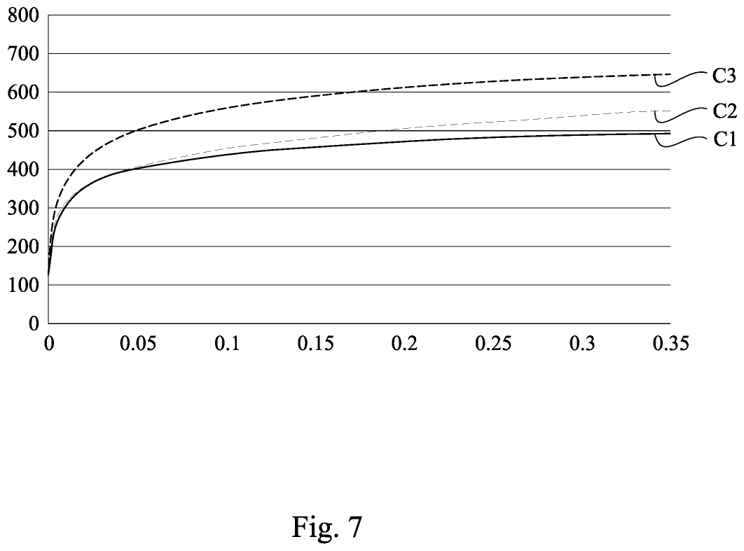

FIG. 6 and FIG. 7 show the numerical simulation of the thermal conduction results for different second surface 124e. References are made to FIG. 2A, FIG. 6 and FIG. 7. In the following descriptions, the simulation environments satisfy the following condition: the temperature of the second surface 124e is 60 degree Celsius. The third surface 124f which is isolated by the circulation tunnel 130 with the second surface 124e is the adiabatic boundary. The second surface 124e and the third surface 124f are both made of copper. The second fluid 150 circulating in the circulation tunnel 130 is water.

FIG. 6 is a diagram of the mechanical energy and the input flow velocity of different types of second surfaces of a heat dissipation device 100. As shown in FIG. 6, the vertical axis is the mechanical energy, and the horizontal axis is the input flow velocity. The first curve C1 corresponds to the smooth structure on the second surface 124e. The second curve C2 corresponds to the protruding strips 124e1 that are circumferentially arranged on the part 112 of the first pipeline 110, and substantially extends along the extending direction of the part 112 of the first pipeline 110, as shown in FIG. 4. The third curve C3 corresponds to the second surface 124e′ which has sequentially arranged spiral shape protruding strips 124e1′, as shown in FIG. 5. From the figures, under the same input flow velocity (e.g. the numerical value of the horizontal axis), the corresponded mechanical energy (e.g. the numerical value of the vertical axis) of the third curve C3 and the second curve C2 both higher than the first curve C1. In other words, no matter which protruding strips 124e1 structure is used, it takes more pump energy to circulate the second fluid 150. And the structure of the third curve C3 (sequentially arranged spiral shape protruding strips 124e1′) costs the highest pump energy. The second surface 124e with protruding strips 124e1 will increase the energy consumptions of the heat dissipation device 100.

FIG. 7 is a diagram of the heat dissipation ability and the mechanical energy of different types of second surfaces of a heat dissipation device. As shown in FIG. 7, the vertical axis is the heat dissipation ability in the unit area, and the horizontal axis is the mechanical energy. From the figure, under the same mechanical energy (e.g. the numerical value of the horizontal axis), the corresponded heat dissipation ability in unit area (e.g. the numerical value of the vertical axis) of the third curve C3 and the second curve C2 both higher than the first curve C1. In other words, no matter which protruding strips 124e1 distribution is used, it will help improve the thermal exchange between the second fluid 150 and the second surface 124e. And the structure of the third curve C3 (sequentially arranged spiral shape protruding strips 124e1′) has the best thermal exchange ability. Compared to the different second surfaces 124e mentioned above, the sequentially arranged spiral shape protruding strips 124e1′ has the best thermal exchange ability, but will lead to the highest energy consumption of the heat dissipation device 100.

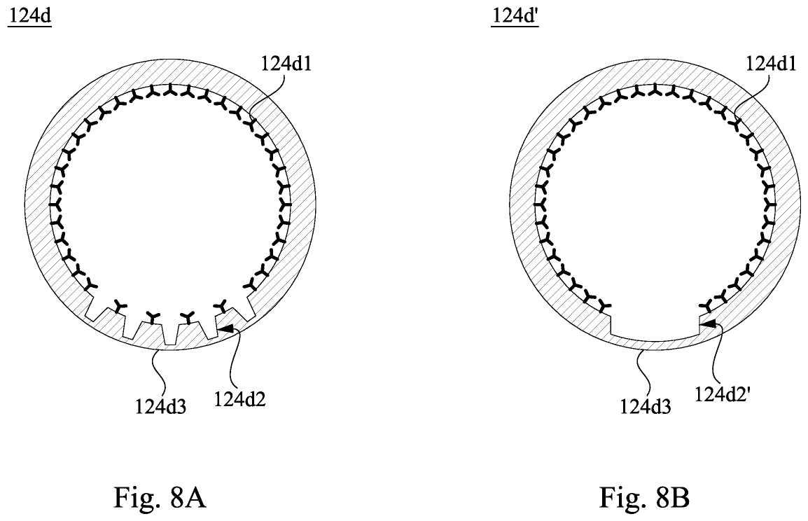

FIG. 8A and FIG. 8B illustrates the cross-sectional view of a part 112 of the first pipeline 110 of a heat dissipation device according to two different embodiments of this disclosure. As shown in FIG. 2A and FIGS. 8A-8B, the first fluid 140 (e.g. refrigerant) passes through the part 112 of the first pipeline 110 and turns into gaseous. The first surface 124d has multiple sharp points 124d1. These sharp points 124d1 increase the surface area of the first surface 124d. The sharp points 124d1 of the first surface 124d contact with the gaseous refrigerant can help to condense the gaseous refrigerant. In some embodiments, the sharp points 124d1 is a Y shape branch structure, but the present disclosure is not limited thereto. In some embodiments, the first surface 124d has at least one groove 124d2. More specifically, in FIG. 8A has multiple narrow grooves 124d2. In another embodiment, as shown in FIG. 8B, one of the first surface 124d′ has one wide groove 124d2′, but the present disclosure is not limited thereto. The grooves 124d2 are located on a side 124d3 of the first surface 124d (e.g. bottom surface). The side 124d3 of the first surface 124d is located on the bottom of the heat dissipation device 100 that is disposed to circulate the first fluid 140 and the second fluid 150. The grooves 124d2 are used to cooperate with the sharp points 124d1, when the first fluid 140 (e.g. gaseous refrigerant) passes through the sharp points 124d1 and condenses, the condensed refrigerant is collected to the grooves 124d2. The first fluid 140 in the grooves 124d2 of the first pipeline 110 can circulate with better efficiency.

In some embodiments, the heat dissipation device 200 contains the structure that is shown in FIG. 3. The first surface 124d is located on the outside of the second pipeline 220, and contacted the first fluid 140. As described above, the sharp points 124d1 of the first surface 124d has the ability to improve the condensation of the first fluid 140. Improving the condensation of the first fluid 140 can improve the heat dissipation efficiency of the heat dissipation device 200.

From the above description of the embodiments of the present disclosure, it can be clearly seen that, in the present disclosure of a heat dissipation device, the second surface that contacts the second fluid has protruding stripes. The protruding stripes can make the second fluid flow in turbulent flow. The turbulent flow can uniformly distribute the heat of the second fluid and increase the thermal exchange efficiency between the second fluid and the first fluid, thus increasing the heat dissipation efficiency of the heat dissipation device. Moreover, the first surface that contacts the first fluid has sharp points to increase the condensation efficiency for the first fluid on the first surface. The above structure can further combine with grooves on the first surface, thus making the condensed first fluid flow more smoothly, and improve the flowing efficiency of the first fluid. The flowing efficiency of the first fluid can further increase the heat dissipation efficiency of the heat dissipation device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A heat dissipation device, comprising:
a first pipeline configured to circulate a first fluid; and
a second pipeline configured to circulate a second fluid and comprising:
a sleeve portion is sleeve with a part of the first pipeline to form a circulation tunnel between the sleeve portion and a part of the first pipeline, one of the sleeve portion and the part of the first pipeline comprising:
a first surface configured to contact the first fluid; and
a second surface configured to contact the second fluid and having a plurality of protruding strips.

2. The heat dissipation device of claim 1, wherein the first surface has a plurality of sharp points.

3. The heat dissipation device of claim 1, wherein the first surface has at least one groove, the at least one groove located on a side of the first surface, and the at least one groove substantially extends along the one of the sleeve portion and the part of the first pipeline and is circumferentially arranged.

4. The heat dissipation device of claim 1, wherein the protruding strips are spiral and are sequentially arranged.

5. The heat dissipation device of claim 1, wherein the protruding strips substantially extend along an extending direction of the one of the sleeve portion and the part of the first pipeline.

6. The heat dissipation device of claim 1, further comprising an input portion and an output portion that are connected to the sleeve portion respectively.

7. The heat dissipation device of claim 6, wherein the sleeve portion is sleeved outside the part of the first pipeline, the circulation tunnel is configured to circulate the second fluid, the first surface is located on an inner side of the first pipeline, and the second surface is located on an outer side of the first pipeline.

8. The heat dissipation device of claim 6, wherein the sleeve portion is sleeved inside the part of the first pipeline, the circulation tunnel is configured to circulate the first fluid, the first surface is located on an outer side of the second pipeline, and the second surface is located on an inner side of the second pipeline.

9. The heat dissipation device of claim 1, further comprising an evaporator connected to two sides of the first pipeline.

10. The heat dissipation device of claim 1, wherein the first fluid is a refrigerant and the second fluid is water.
